(19) United States
(12) Patent Application Publication
(10) Pub. No.: US 2025/0143115 A1
(43) Pub. Date: May 1, 2025

(54) DISPLAY DEVICE AND METHOD OF MANUFACTURING THE SAME

(71) Applicant: Samsung Display Co., LTD., Yongin-si (KR)

(72) Inventors: Jung Kyu CHOI, Yongin-si (KR); Hyeong Jun KIM, Yongin-si (KR); Ju An NA, Yongin-si (KR); Ki Sik BAN, Yongin-si (KR); Su Chang RYU, Yongin-si (KR); Suk Ho CHOI, Yongin-si (KR)

(21) Appl. No.: 18/753,012

(22) Filed: Jun. 25, 2024

(30) Foreign Application Priority Data
Oct. 25, 2023 (KR) 10-2023-0143957

(51) Int. Cl. H10K 59/131; H10K 59/12; H10K 71/60

(52) U.S. Cl. CPC H10K 59/131; H10K 59/1201; H10K 71/611

(57) ABSTRACT

A display device includes a plate including an open part, a lower film disposed on the plate, a first substrate disposed on the lower film, a first connection line disposed on the first substrate, a pad part inserted into a first contact hole penetrating through the first connection line, the first substrate, and the lower film, where the pad part is connected to the first connection line, and a flexible film including a first lead electrode inserted into the open part of the plate. The first lead electrode includes a pin part protruding from an upper surface of the first lead electrode and penetrating through the pad part.

This application claims priority to Korean Patent Application No. 10-2023-0143957, filed on Oct. 25, 2023, and all the benefits accruing therefrom under 35 U.S.C. § 119, the content of which in its entirety is herein incorporated by reference.

### BACKGROUND

### 1. Technical Field

The present disclosure relates to a display device and a method of manufacturing the display device.

### 2. Description of the Related Art

With the advancement of the information age, the demand for display devices for displaying images has increased and diversified. For example, display devices have been applied to various electronic devices such as, for example, smartphones, digital cameras, laptop computers, navigation devices, and smart televisions. The display devices may be flat panel display devices such as, for example, liquid crystal display devices, field emission display devices, or organic light emitting display devices. Among such flat panel display devices, a light emitting display device may display an image without a backlight unit providing light to a display panel because each pixel of the display panel may include light emitting elements that may emit light by themselves.

### SUMMARY

Aspects of the present disclosure provide a display device in which a pad part may easily connect a lead electrode disposed below a substrate and a connection line disposed above the substrate to each other by filling a micro hole with conductive ink to form the pad part, and a method of manufacturing the display device.

Aspects of the present disclosure also provide a display device capable of reducing manufacturing time and manufacturing costs by minimizing an area of a non-display area and simplifying a manufacturing process, and a method of manufacturing the display device.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an embodiment, a display device includes a plate including an open part, a lower film disposed on the plate, a first substrate disposed on the lower film, a first connection line disposed on the first substrate, a pad part inserted into a first contact hole penetrating through the first connection line, the first substrate, and the lower film, where the pad part is connected to the first connection line, and a flexible film including a first lead electrode inserted into the open part of the plate. The first lead electrode includes a pin part protruding from an upper surface of the first lead electrode and penetrating through the pad part.

A lower surface of the pad part may be in contact with the upper surface of the first lead electrode.

A lower surface of the pad part may be spaced apart from the upper surface of the first lead electrode.

The display device may further include a gate insulating layer disposed on the first substrate, a second connection line disposed on the gate insulating layer and connected to the first connection line, and an interlayer insulating layer disposed between the second connection line and the first connection line.

The display device may further include a semiconductor region of a transistor disposed on the second substrate, a gate electrode of the transistor disposed on the gate insulating layer, and a connection electrode disposed on the interlayer insulating layer and electrically connected to the transistor. The first connection line may include the same material as the connection electrode and is formed in the same process as the connection electrode. The second connection line may include the same material as the gate electrode of the transistor and is formed in the same process as the gate electrode of the transistor.

The display device may further include a printed circuit unit disposed below the plate and including a driving integrated circuit. The flexible film may further include a second lead electrode electrically connected to the printed circuit unit.

According to an embodiment, a display device includes a plate including a lead line, a lower film disposed on the plate, a first substrate disposed on the lower film, a first connection line disposed on the first substrate, and a pad part inserted into a first contact hole penetrating through the first connection line, the first substrate, and the lower film, where the pad part is connected to the first connection line. The lead line includes a first portion disposed on an upper surface of the plate, a second portion penetrating through the plate and connected to the first portion, a third portion disposed on a lower surface of the plate and connected to the second portion, and a pin part protruding from an upper surface of the first portion and penetrating through the pad part.

A lower surface of the pad part may be in contact with the upper surface of the first portion of the lead line.

A lower surface of the pad part may be spaced apart from the upper surface of the first portion of the lead line.

The display device may further include a display driver disposed on the lower surface of the plate and electrically connected to the third portion of the lead line.

According to an embodiment, a method of manufacturing a display device includes sequentially stacking a lower film, a first substrate, a first connection line, and a protective film, forming a first contact hole penetrating through the protective film, the first connection line, the first substrate, and the lower film, providing the lower film, the first substrate, the first connection line, and the protective film that include the first contact hole, on a stage, providing a print head over the first contact hole, supplying a positive voltage to the print head and supplying a negative voltage to the stage, by a power supply, injecting conductive ink into the first contact hole through the print head, forming a pad part by sintering the conductive ink, disposing a plate below the lower film, the plate including an open part exposing the pad part, and connecting a first lead electrode of a flexible film to the pad part by inserting the first lead electrode of the flexible film into the open part.

The injecting of the conductive ink may include filling the first contact hole with the conductive ink by electrical attraction of the conductive ink having a positive charge.

The injecting of the conductive ink may include injecting a portion of the conductive ink into the first contact hole and applying another portion of the conductive ink onto the protective film, by applying the conductive ink in a linear direction by the print head.

The method of manufacturing a display device may further include, after the forming of the pad part, removing the protective film and the conductive ink applied onto the protective film.

According to an embodiment, a method of manufacturing a display device includes sequentially stacking a protective film, a lower film, a first substrate, and a first connection line, forming a first contact hole penetrating through the first connection line, the first substrate, the lower film, and the protective film, providing a stage including soldering ink provided at an upper portion of the stage, providing the protective film, the lower film, the first substrate, and the first connection line on the stage such that the first contact hole overlaps the soldering ink, suctioning the soldering ink into the first contact hole by a suction device, and forming a pad part by sintering the soldering ink.

The method of manufacturing a display device may further include exposing a lower surface of the lower film by removing the protective film, disposing a plate below the lower film, the plate including an open part exposing the pad part, and connecting a first lead electrode of a flexible film to the pad part by inserting the first lead electrode of the flexible film into the open part.

The exposing of the lower surface of the lower film may include disposing a lower surface of the pad part on the same plane as the lower surface of the lower film.

According to an embodiment, a method of manufacturing a display device includes sequentially stacking a lower film, a first substrate, and a first connection line, forming a first contact hole penetrating through the first connection line, the first substrate, and the lower film, providing a first lead electrode disposed on one side of a flexible film and including a pin part protruding from an upper surface of the first lead electrode, disposing the first lead electrode on a lower surface of the lower film by inserting the pin part into the first contact hole, injecting conductive ink into the first contact hole through a print head, and forming a pad part by sintering the conductive ink.

The pin part may penetrate through the pad part and protrudes from an upper surface of the pad part.

The first lead electrode may be electrically connected to the first connection line through the pin part and the pad part.

With a display device and a method of manufacturing the same according to example embodiments, by filling a micro hole with conductive ink to form a pad part, the pad part may easily connect a lead electrode disposed below a substrate and a connection line disposed above the substrate to each other. Aspects of the display device and the method of manufacturing the display device support reducing manufacturing time and manufacturing costs by minimizing the size of a non-display area and simplifying a manufacturing process.

The effects of the present disclosure are not limited to the aforementioned effects, and various other effects are included in the present specification.

### BRIEF DESCRIPTION OF THE DRAWINGS

The above and other aspects and features of the present disclosure will become more apparent by describing in detail example embodiments thereof with reference to the attached drawings, in which:

FIG. 1 is a plan view illustrating a display device according to an example embodiment;

FIG. 2 is a cross-sectional view taken along line I-I′ of FIG. 1;

FIG. 3 is a bottom view illustrating the display device according to an example embodiment;

FIG. 4 is a plan view illustrating a portion of a non-display area of the display device according to an example embodiment;

FIG. 5 is a cross-sectional view illustrating a portion of the display device according to an example embodiment;

FIG. 6 is a cross-sectional view illustrating a portion of a display device according to another example embodiment;

FIGS. 7 to 9 are cross-sectional views illustrating an example of a manufacturing process of a pad part in the display devices of FIGS. 5 and 6;

FIGS. 10 to 12 are perspective views illustrating an example of a manufacturing process of the pad part in the display devices of FIGS. 5 and 6;

FIGS. 13 to 16 are cross-sectional views illustrating another example of manufacturing processes of the pad part in the display devices of FIGS. 5 and 6;

FIG. 17 is a cross-sectional view illustrating a portion of a display device according to another example embodiment;

FIG. 18 is a cross-sectional view illustrating a portion of a display device according to another example embodiment;

FIG. 19 is a cross-sectional view illustrating a portion of a display device according to another embodiment;

FIG. 20 is a cross-sectional view illustrating a portion of a display device according to another example embodiment; and

FIGS. 21 to 23 are cross-sectional views illustrating a manufacturing process of a pad part in the display devices of FIGS. 17 to 20.

### DETAILED DESCRIPTION

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods employing one or more of the disclosure disclosed herein. It is apparent, however, that various embodiments may be practiced without these specific details or with one or more equivalent arrangements. In other instances, structures and devices are illustrated in block diagram form in order to avoid unnecessarily obscuring various embodiments. Further, various embodiments may be different, but do not have to be exclusive nor limit the disclosure. For example, specific shapes, configurations, and characteristics of an embodiment may be used or implemented in other embodiments without departing from the disclosure.

Unless otherwise specified, the illustrated embodiments are to be understood as providing features of varying detail of some ways in which the disclosure may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as, for example, a layer, is referred to as being “on,” “connected to,” or “coupled to” another element or layer, the layer may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Further, the X-axis, the Y-axis, and the Z-axis are not limited to three axes of a rectangular coordinate system, and thus the X-, Y-, and Z-axes, and may be interpreted in a broader sense. For example, the X-axis, the Y-axis, and the Z-axis may be perpendicular to one another, or may represent different directions that are not perpendicular to one another.

For the purposes of this disclosure, “at least one of X, Y, and Z” and “at least one selected from the group consisting of X, Y, and Z” may be construed as X only, Y only, Z only, or any combination of two or more of X, Y, and Z, such as, for example, for instance, XYZ, XYY, YZ, ZZ, or the like. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as, for example, “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature, and the shapes of these regions may not reflect actual shapes of regions of a device and, as such, are not necessarily intended to be limiting.

As customary in the field, some embodiments are described and illustrated in the accompanying drawings in terms of functional blocks, units, parts, and/or modules. Those skilled in the art will appreciate that these blocks, units, parts, and/or modules are physically implemented by electronic (or optical) circuits, such as, for example, logic circuits, discrete components, microprocessors, hard-wired circuits, memory elements, wiring connections, and the like, which may be formed using semiconductor-based fabrication techniques or other manufacturing technologies. In the case of the blocks, units, parts, and/or modules being implemented by microprocessors or other similar hardware, they may be programmed and controlled using software (e.g., microcode) to perform various functions discussed herein and may optionally be driven by firmware and/or software. It is also contemplated that each block, unit, part, and/or module may be implemented by dedicated hardware, or as a combination of dedicated hardware to perform some functions and a processor (e.g., one or more programmed microprocessors and associated circuitry) to perform other functions. Also, each block, unit, part, and/or module of some embodiments may be physically separated into two or more interacting and discrete blocks, units, parts, and/or modules without departing from the scope of the disclosure. Further, the blocks, units, parts, and/or modules of some embodiments may be physically combined into more complex blocks, units, parts, and/or modules without departing from the scope of the disclosure.

Unless otherwise defined or implied herein, all terms (including technical and scientific terms) used herein have the same meaning as commonly understood by those skilled in the art to which this disclosure pertains. It will be further understood that terms, such as, for example, those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, detailed embodiments of the disclosure are described with reference to the accompanying drawings.

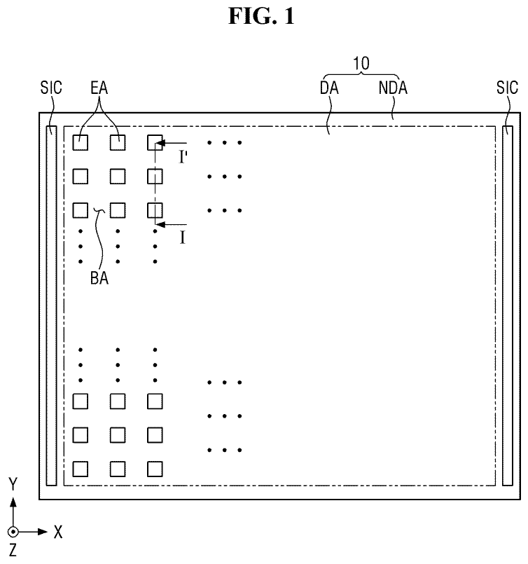

FIG. 1 is a plan view illustrating a display device according to an example embodiment.

Referring to FIG. 1, a display device 10 may be applied to portable electronic devices such as, for example, mobile phones, smartphones, tablet personal computers (PCs), mobile communication terminals, electronic notebooks, electronic books, portable multimedia players (PMPs), navigation devices, and ultra mobile PCs (UMPCs). As another example, the display device 10 may be applied as a display unit of televisions, laptop computers, monitors, billboards, or the Internet of Things (IOTs). As another example, the display device 10 may be applied to wearable devices such as, for example, smart watches, watch phones, glasses-type displays, and head mounted displays (HMDs).

The display device 10 may have a shape similar to a rectangular shape in a plan view. For example, the display device 10 may be rectangular shaped in a plan view. In an example, a corner of the display device 10 where a side in an X-axis direction and a side in a Y-axis direction meet may be rounded according to a predetermined curvature or a right-angle. The shape of the display device 10 in a plan view is not limited to the rectangular shape, and may be a shape similar to other polygonal shapes, a circular shape, or an elliptical shape. For example, the display device 10 may be polygonal shaped, circular shaped, or elliptical shaped.

The display device 10 may include a display area DA and a non-display area NDA. The display area DA may include a plurality of pixels configured to display an image. Each of the plurality of pixels may include an organic light emitting diode (LED) including an organic light emitting layer, a quantum dot LED including a quantum dot light emitting layer, an inorganic LED including an inorganic semiconductor, or a micro LED. Hereinafter, it will be mainly described that each of the plurality of pixels includes an organic light emitting diode, but embodiments of the present disclosure are not limited thereto.

The plurality of pixels may be arranged along a plurality of rows and columns in the display area DA. Each of the plurality of pixels may include an emission area EA defined by a pixel defining film or a bank and may emit light having a predetermined peak wavelength through the emission area EA. The emission area EA may be an area in which light generated by a light emitting element of the display device 10 is emitted to the outside of the display device 10.

The display area DA of the display device 10 may include a light blocking area BA surrounding a plurality of emission areas EA. The light blocking area BA may prevent color mixing of light emitted from the emission areas EA.

The non-display area NDA may be disposed around the display area DA and surround the display area DA, and the non-display area NDA may not display an image. The non-display area NDA may include scan drivers SIC supplying scan signals to the display area DA. The scan drivers SIC may be disposed on the left side and the right side of the non-display area NDA. The scan drivers SIC may generate the scan signals based on a scan control signal. The scan control signal may include a start signal, a clock signal, and a source voltage, but is not limited thereto. The scan drivers SIC may supply the scan signals to scan lines of the display area DA according to a set order.

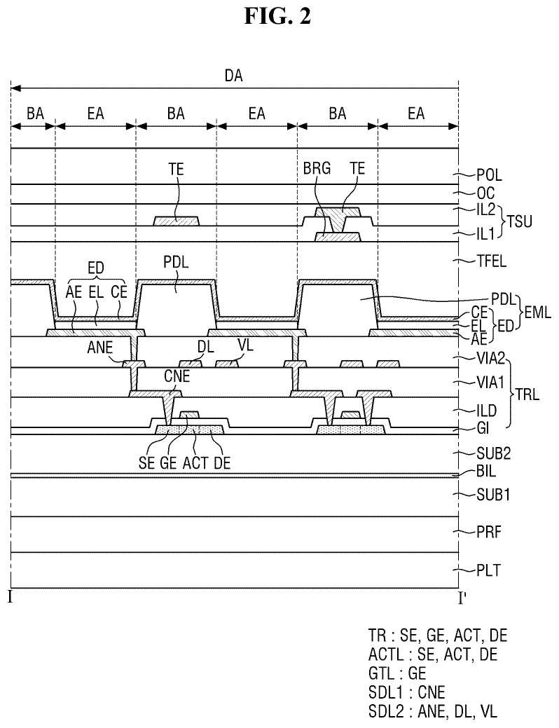

FIG. 2 is a cross-sectional view taken along line I-I′ of FIG. 1.

Referring to FIG. 2, the display area DA of the display device 10 may include a plurality of emission areas EA. Each of the emission areas EA may be an area in which light generated by a light emitting element ED is emitted to the outside of the display device 10.

The display device 10 may include a plate PLT, a lower film PRF, a first substrate SUB1, a barrier insulating layer BIL, a second substrate SUB2, a transistor layer TRL, a light emitting element layer EML, an encapsulation layer TFEL, a touch sensing unit TSU, a planarization layer OC, and an optical member POL.

The plate PLT may support the display device 10. The plate PLT may include a material having excellent permeability and heat resistance (e.g., a material satisfying target permeability and heat resistance thresholds). For example, the plate PLT may be formed of a glass fiber reinforced polymer (GFRP), but is not limited thereto.

The lower film PRF may be disposed on the plate PLT and protect a lower portion of the display device 10. For example, the lower film PRF may include at least one of an acrylic resin, an epoxy resin, a phenolic resin, a polyamides resin, an unsaturated polyesters resin, a polyphenylene ethers resin, a polyphenylene sulfides resin, and a benzocyclobutenes resin. The lower film PRF may have flexible characteristics such that the lower film PRF is capable of being bent, folded, or rolled, but is not limited thereto.

The first substrate SUB1 may be disposed on the lower film PRF. The first substrate SUB1 may be a base substrate or a base member. The first substrate SUB1 may be a flexible substrate that may be bent, folded, or rolled. For example, the first substrate SUB1 may include an insulating material such as, for example, a polymer resin, for example, polyimide (PI), but is not limited thereto.

The barrier insulating layer BIL may be disposed on the first substrate SUB1. The barrier insulating layer BIL may include an inorganic film capable of preventing permeation of air or moisture. For example, the barrier insulating layer BIL may include at least one of a silicon nitride layer, a silicon oxynitride layer, a silicon oxide layer, a titanium oxide layer, an aluminum oxide layer, and an amorphous silicon layer, but is not limited thereto.

The second substrate SUB2 may be disposed on the barrier insulating layer BIL. The second substrate SUB2 may be a base substrate or a base member. The second substrate SUB2 may be a flexible substrate that may be bent, folded, or rolled. For example, the second substrate SUB2 may include an insulating material such as, for example, a polymer resin, for example, polyimide (PI), but is not limited thereto.

The transistor layer TRL may be disposed on the second substrate SUB2. The transistor layer TRL may include a plurality of transistors TR constituting pixel circuits of the pixels. The transistor layer TRL may include scan lines, data lines DL, and power lines VL connected to the pixels. Each of the transistors TR may include a semiconductor region ACT, a drain electrode DE, a source electrode SE, and a gate electrode GE. In an example in which the scan driver SIC is formed on one side of the non-display area NDA, the scan driver SIC may include transistors TR.

The transistor layer TRL may include an active layer ACTL, a gate insulating layer GI, a gate layer GTL, an interlayer insulating layer ILD, a first source metal layer SDL1, a first via layer VIA1, a second source metal layer SDL2, and a second via layer VIA2.

The active layer ACTL may be disposed on the second substrate SUB2. The active layer ACTL may include the semiconductor region ACT, the drain electrode DE, and the source electrode SE of the transistor TR. The semiconductor region ACT may overlap the gate electrode GE, and the semiconductor region ACT may be insulated from the gate electrode GE by the gate insulating layer GI. The drain electrode DE and the source electrode SE may be provided by forming a material of the semiconductor region ACT conductors. The transistor TR may constitute the pixel circuit of each of the plurality of pixels.

The gate insulating layer GI may be disposed on the active layer ACTL. The gate insulating layer GI may insulate the semiconductor region ACT and the gate electrode GE of the transistor TR from each other. The gate insulating layer GI may include a contact hole through which a connection electrode CNE penetrates.

The gate layer GTL may be disposed on the gate insulating layer GI. The gate layer GTL may include the gate electrode GE of the transistor TR. The gate electrode GE may overlap the semiconductor region ACT, with the gate insulating layer GI interposed the gate electrode GE and the semiconductor region ACT. The gate electrode GE may receive a scan signal from the scan line. For example, the gate layer GTL may be formed as a single layer or multiple layers including at least one of molybdenum (Mo), aluminum (Al), chromium (Cr), gold (Au), silver (Ag), titanium (Ti), nickel (Ni), palladium (Pd), indium (In), neodymium (Nd), and copper (Cu).

The interlayer insulating layer ILD may be disposed on the gate layer GTL. The interlayer insulating layer ILD may insulate the gate layer GTL and the first source metal layer SDL1 from each other. The interlayer insulating layer ILD may include a contact hole through which the connection electrode CNE penetrates.

The first source metal layer SDL1 may be disposed on the interlayer insulating layer ILD. The first source metal layer SDL1 may include the connection electrode CNE. The connection electrode CNE may be inserted into the contact hole penetrating through the interlayer insulating layer ILD and the gate insulating layer GI, and the connection electrode CNE may be connected to the source electrode SE of the transistor TR. The connection electrode CNE may electrically connect the transistor TR and an anode connection electrode ANE to each other. The connection electrode CNE may supply a driving current received from the pixel circuit to the light emitting element ED through the anode connection electrode ANE. For example, the first source metal layer SDL1 may be formed as a single layer or multiple layers including at least one of molybdenum (Mo), aluminum (Al), chromium (Cr), gold (Au), silver (Ag), titanium (Ti), nickel (Ni), palladium (Pd), indium (In), neodymium (Nd), and copper (Cu).

The first via layer VIA1 may be disposed on the first source metal layer SDL1. The first via layer VIA1 may planarize an upper end of the pixel circuit and protect the pixel circuit. The first via layer VIA1 may include an organic insulating material such as, for example, polyimide (PI). The first via layer VIA1 may include a contact hole through which the anode connection electrode ANE penetrates.

The second source metal layer SDL2 may be disposed on the first source metal layer SDL1. The second source metal layer SDL2 may include the anode connection electrode ANE, the data line DL, and the power line VL. The second source metal layer SDL2 may include a same material as included in the first source metal layer SDL1.

The anode connection electrode ANE may be inserted into a contact hole penetrating through the first via layer VIA1 to be connected to the connection electrode CNE. The anode connection electrode ANE may electrically connect the connection electrode CNE and a pixel electrode AE of the light emitting element ED to each other. The anode connection electrode ANE may supply the driving current received from the connection electrode CNE to the light emitting element ED.

The data line DL may extend in the Y-axis direction in the display area DA. The data line DL may be electrically connected to the transistor TR. The data line DL may supply a data voltage to the pixel circuit.

The power line VL may extend in the Y-axis direction in the display area DA. The power line VL may be electrically connected to the transistor TR or the light emitting element ED. For example, the power line VL may be a high potential line, a low potential line, an initialization voltage line, a reference voltage line, or a bias voltage line, but is not limited thereto.

The second via layer VIA2 may be disposed on the second source metal layer SDL2. The second via layer VIA2 may planarize an upper end of the transistor layer TRL. The second via layer VIA2 may include an organic insulating material such as, for example, polyimide (PI). The second via layer VIA2 may include a contact hole through which the pixel electrode AE penetrates.

The light emitting element layer EML may be disposed on the transistor layer TRL. The light emitting element layer EML may include the light emitting element ED and a pixel defining film PDL.

The light emitting element ED may be disposed in the emission area EA on the second via layer VIA2. The light emitting element ED of each of the plurality of pixels may include the pixel electrode AE, a light emitting layer EL, and a common electrode CE. The pixel electrode AE may be disposed on the second via layer VIA2. The pixel electrode AE may overlap one of the plurality of emission areas EA defined by the pixel defining film PDL. For example, the pixel electrode AE may receive the driving current from the pixel circuit through the anode connection electrode ANE and the connection electrode CNE.

The light emitting layer EL may be disposed on the pixel electrode AE. For example, the light emitting layer EL may be an organic light emitting layer formed of an organic material, but is not limited thereto. In a case where the light emitting layer EL is the organic light emitting layer, when the pixel circuit of the pixel applies a predetermined voltage to the pixel electrode AE and the common electrode CE receives a common voltage or a cathode voltage, holes and electrons may move to the light emitting layer EL through a hole transporting layer and an electron transporting layer, respectively, and the holes and electrons may combine with each other in the light emitting layer EL to emit light. For example, the pixel electrode may be an anode electrode and the common electrode may be a cathode electrode, but embodiments of the present disclosure are not limited thereto.

As another example, a plurality of light emitting elements may include quantum dot light emitting diodes including a quantum dot light emitting layer, inorganic light emitting diodes including an inorganic semiconductor, or micro light emitting diodes.

The common electrode CE may be disposed on the light emitting layer EL. For example, the common electrode CE is not divided for each of the plurality of pixels, and the common electrode CE may be implemented in the form of an electrode common to all the pixels. The common electrode CE may be disposed on the light emitting layers EL in the plurality of emission areas EA, and the common electrode CE may be disposed on the pixel defining film PDL in the light blocking area BA.

The pixel defining film PDL may be disposed in the light blocking area BA on the second via layer VIA2. The pixel defining film PDL may define the plurality of emission areas EA or a plurality of opening areas. The pixel electrodes AE of the plurality of pixels may be spaced apart and insulated from each other by the pixel defining film PDL.

The encapsulation layer TFEL may be disposed on the common electrode CE and may cover the plurality of light emitting elements ED. The encapsulation layer TFEL may include at least one inorganic film and prevent oxygen or moisture from permeating into the plurality of light emitting elements ED. The encapsulation layer TFEL may include at least one organic film which protects the plurality of light emitting elements ED from foreign substances such as, for example, dust.

The touch sensing unit TSU may be disposed on the encapsulation layer TFEL. The touch sensing unit TSU may include a bridge electrode BRG, a first insulating layer IL1, touch electrodes TE, and a second insulating layer IL2.

The bridge electrode BRG may be disposed on the encapsulation layer TFEL. The bridge electrode BRG may be disposed at a different layer than the touch electrodes TE and may electrically connect adjacent touch electrodes TE to each other.

The first insulating layer IL1 may be disposed on the bridge electrode BRG. The first insulating layer IL1 may have insulating and optical functions. As an example, the first insulating layer IL1 may be an inorganic film including at least one of a silicon nitride layer, a silicon oxynitride layer, a silicon oxide layer, a titanium oxide layer, and an aluminum oxide layer. As another example, the first insulating layer IL1 may include an organic film.

The touch electrodes TE may be disposed in the light blocking area BA on the first insulating layer IL1. The touch electrodes TE may sense a touch input by a user in a capacitance manner. For example, the touch sensing unit TSU may sense the touch input in a mutual capacitance manner in which capacitance is formed between a plurality of touch electrodes TE or a self-capacitance manner in which capacitance is formed in each of the plurality of touch electrodes TE. The touch electrode TE may be formed as a single layer formed of molybdenum (Mo), titanium (Ti), copper (Cu), aluminum (Al), or indium tin oxide (ITO) or be formed as a stacked structure (Ti/Al/Ti) of aluminum and titanium, a stacked structure (ITO/AI/ITO) of aluminum and ITO, an APC alloy, and a stacked structure (ITO/APC/ITO) of an APC alloy and ITO.

The second insulating layer IL2 may be disposed on the touch electrodes TE. The second insulating layer IL2 may have insulating and optical functions. The second insulating layer IL2 may be formed of the material included in the first insulating layer IL1.

The planarization layer OC may be disposed on the touch sensing unit TSU and planarize an upper end of the touch sensing unit TSU. For example, the planarization layer OC may include an organic insulating material.

The optical member POL may be disposed on the planarization layer OC. The optical member POL may be attached onto the touch sensing unit TSU by an optically clear adhesive (OCA) film or an optically clear resin (OCR). For example, the optical member POL may include a linear polarizer and a phase retardation film, and the phase retardation film may be a λ/4 plate (quarter-wave plate). The phase retardation film and the linear polarizer may be sequentially stacked on the touch sensing unit TSU. The optical member POL may prevent distortion of colors due to external light reflection by reducing reflected light by external light.

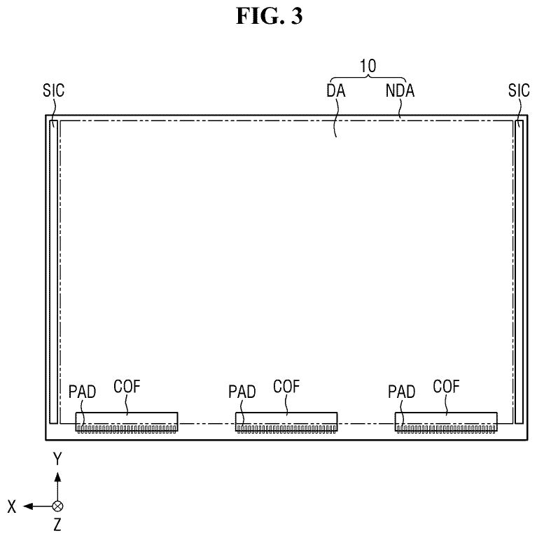

FIG. 3 is a bottom view illustrating the display device according to an example embodiment.

Referring to FIG. 3, flexible films COF may be disposed below the plate PLT. The flexible films COF may be disposed at an edge of a lower surface of the display device 10. Lead electrodes of the flexible films COF may be in contact with lower surfaces of pad parts PAD. The pad parts PAD may be disposed in the non-display area NDA, but are not limited to thereto. The flexible film COF may supply a data voltage received from a printed circuit unit to the data line DL of the display area DA through the pad part PAD. The flexible film COF may supply a source voltage received from the printed circuit unit to the power line VL of the display area DA through the pad part PAD. The flexible film COF may supply a scan control signal to the scan driver SIC through the pad part PAD. The display device 10 may include a first connection line CWL1 disposed on the second substrate SUB2, the pad part PAD penetrating through the first and second substrates SUB1 and SUB2, and the flexible film COF and the printed circuit unit disposed below the lower film PRF, which may minimize an area of the display area NDA.

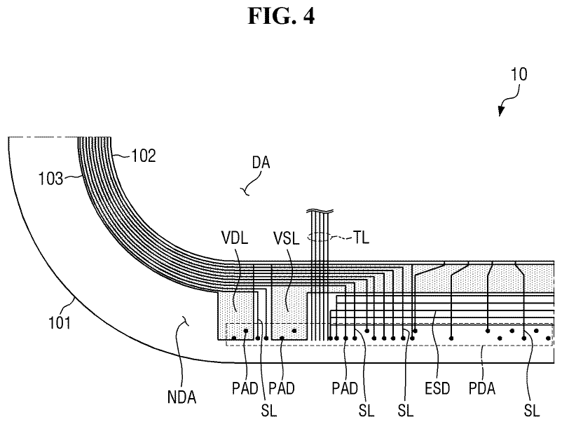

FIG. 4 is a plan view illustrating a portion of a non-display area of the display device according to an example embodiment.

Referring to FIG. 4, the non-display area NDA may include signal lines SL, a high potential line VDL, a low potential line VSL, and touch lines TL. The signal lines SL, the high potential line VDL, the low potential line VSL, and the touch lines TL may extend from a pad area PDA to the display area DA. The signal line SL may be electrically connected to the data line DL and supply the data voltage, and the signal line SL may be electrically connected to the scan driver SIC and supply the scan control signal. The high potential line VDL may be electrically connected to the power line VL of the display area DA and supply a high potential voltage to the pixel circuit. The low potential line VSL may be electrically connected to the common electrode CE of the light emitting element ED and supply a low potential voltage. The touch lines TL may be electrically connected to the touch electrodes TE of the touch sensing unit TSU and supply touch driving signals. The signal lines SL, the high potential line VDL, the low potential line VSL, and the touch lines TL may receive signals or voltages from the flexible films COF disposed on the lower portion of the display device 10 through the pad parts PAD.

The non-display area NDA may further include an anti-static circuit ESD. The anti-static circuit ESD may overlap the signal line SL and may be electrically connected to the signal line SL. Accordingly, the anti-static circuit ESD may prevent static electricity introduced from the outside from being introduced into the display area DA through the signal line SL.

A solid line 101 of FIG. 4 indicates a boundary of the display device 10 corresponding to any one corner of the display device 10. A solid line 102 of FIG. 4 is a virtual line indicating a boundary between the non-display area NDA and the display area DA of the display device 10. A solid line 103 of FIG. 4 is a line indicating a boundary where the encapsulation layer TFEL of the display device 10 is disposed. Accordingly, the signal line SL, the high potential line VDL, and the low potential line VSL may extend to the pad parts PAD along the non-display area NDA inside the boundary where the encapsulation layer TFEL is disposed. The signal line SL, the high potential line VDL, and the low potential line VSL may be disposed such that the signal line SL, the high potential line VDL, and the low potential line VSL are not outside the encapsulation layer TFEL beyond the encapsulation layer TFEL.

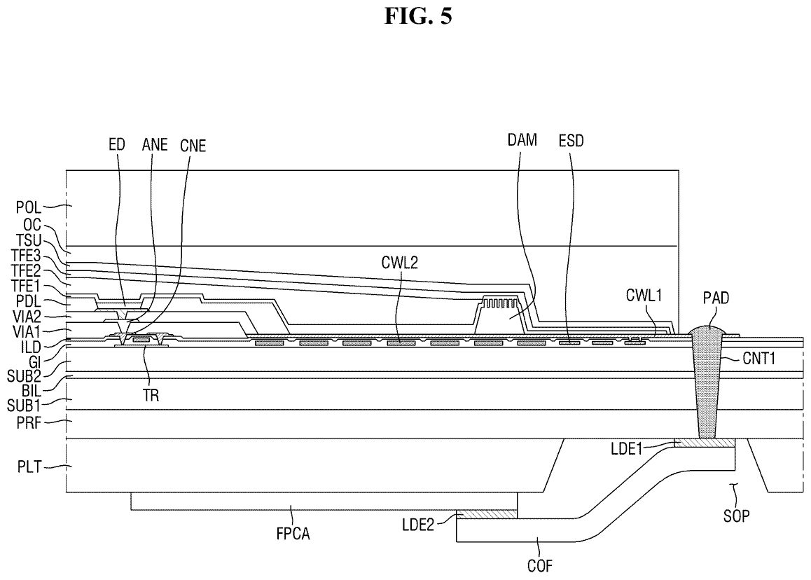

FIG. 5 is a cross-sectional view illustrating a portion of the display device according to an example embodiment. Hereinafter, the same configurations as the configurations described herein will be briefly described or a description thereof will be omitted.

Referring to FIG. 5, the display device 10 may include a plate PLT, a lower film PRF, a first substrate SUB1, a barrier insulating layer BIL, a second substrate SUB2, a transistor layer TRL, a light emitting element layer EML, an encapsulation layer TFEL, a dam DAM, an anti-static circuit ESD, a touch sensing unit TSU, a planarization layer OC, an optical member POL, a pad part PAD, a flexible film COF, and a printed circuit unit FPCA.

A first connection line CWL1 may be disposed on the interlayer insulating layer ILD. The first connection line CWL1 may include the same material as the first source metal layer SDL1 of the display area DA and may be formed in the same process as the first source metal layer SDL1. One portion of the first connection line CWL1 may be in contact with the pad part PAD penetrating through the first connection line CWL1. The other portion of the first connection line CWL1 may penetrate through the interlayer insulating layer ILD and be in contact with a second connection line CWL2. The first connection line CWL1 may electrically connect the pad part PAD and the second connection line CWL2 to each other. The first connection line CWL1 may supply a data voltage or a source voltage received from the pad part PAD to the second connection line CWL2.

The second connection line CWL2 may be disposed on the gate insulating layer GI. The second connection line CWL2 may include the same material as the gate layer GTL of the display area DA and may be formed in the same process as the gate layer GTL. The second connection line CWL2 may supply the data voltage received from the first connection line CWL1 to the data line DL, and the second connection line CWL2 may supply the source voltage received from the first connection line CWL1 to the power line VL. For example, the second connection line CWL2 may correspond to the signal line SL of FIG. 4 or may be electrically connected to the signal line SL.

Optionally, the second connection line CWL2 may be omitted. In this case, the first connection line CWL1 may be electrically connected to the data line DL or the power line VL.

The pad part PAD may be disposed on the first connection line CWL1 and inserted into a first contact hole CNT1. The first contact hole CNT1 may penetrate through the first connection line CWL1, the interlayer insulating layer ILD, the gate insulating layer GI, the second substrate SUB2, the barrier insulating layer BIL, the first substrate SUB1, and the lower film PRF. The first contact hole CNT1 may be etched from an upper surface of the first connection line CWL1 and penetrate up to a lower surface of the lower film PRF. An upper surface of the pad part PAD may protrude from the upper surface of the first connection line CWL1, and a lower surface of the pad part PAD may be disposed on the same plane as the lower surface of the lower film PRF. In a manufacturing process of the display device 10, the lower surface of the pad part PAD may be exposed through an open part SOP of the plate PLT. The pad part PAD may electrically connect a first lead electrode LDE1 of the flexible film COF and the first connection line CWL1 to each other. The pad part PAD may be formed as a single layer or multiple layers including at least one of molybdenum (Mo), aluminum (Al), chromium (Cr), gold (Au), silver (Ag), titanium (Ti), nickel (Ni), palladium (Pd), indium (In), neodymium (Nd), and copper (Cu).

As an example, the pad part PAD may be formed by low temperature sintering of conductive ink including nanoparticles and a polymer. The nanoparticles may include nanoscale metal particles such as, for example, silver (Ag), copper (Cu), aluminum (Al), or chromium (Cr), and the polymer may include an acrylic resin or an epoxy resin, but embodiments of the present disclosure are not limited thereto. The conductive ink may include the polymer as a binder binding the metal particles to each other, and the nanoparticles may be in close contact (e.g., within a threshold distance) with each other and agglomerate through a sintering process. The pad part PAD may have conductivity by including the sintered nanoparticles.

As another example, the pad part PAD may be formed by low temperature sintering of metal organic decomposition ink (MOD Ink). The metal organic decomposition ink may include liquid-phase metal organic decomposition materials smaller than the nanoparticles, and the liquid-phase metal organic decomposition materials may be changed into metal materials through a sintering process. Accordingly, the pad part PAD may have conductivity.

The pad part PAD may be formed by injecting the conductive ink or metal paste into the first contact hole CNT1 and then sintering the conductive ink or the metal paste using intense pulsed light (IPL) or a laser beam. Specific resistance of the pad part PAD may be reduced because the metal particles are in close contact with each other and agglomerate due to heat generated by the IPL or the laser beam in the sintering process.

The first contact hole CNT1 may have a width in micrometer (μm) units. For example, the width of the first contact hole CNT1 may be 40 μm or less. The conductive ink may have a droplet size in nanometer (nm) units. For example, the droplet size of the conductive ink may be 500 nm or more. The display device 10 includes a plurality of micro-holes penetrating through the first connection line CWL1, the interlayer insulating layer ILD, the gate insulating layer GI, the second substrate SUB2, the barrier insulating layer BIL, the first substrate SUB1, and the lower film PRF, and thus, aspects of the display device 10 support minimizing the size of the non-display area NDA and simplifying a manufacturing process, which may reduce manufacturing time and manufacturing costs.

The encapsulation layer TFEL may include first to third encapsulation layers TFE1, TFE2, and TFE3.

The first encapsulation layer TFE1 may be disposed on the light emitting element layer EML. The first encapsulation layer TFE1 may include an inorganic material and prevent oxygen or moisture from permeating into the light emitting element layer EML. The first encapsulation layer TFE1 may extend to an edge of the planarization layer OC beyond the display area DA and the dam DAM. For example, the first encapsulation layer TFE1 may include at least one of a silicon nitride layer, a silicon oxynitride layer, a silicon oxide layer, a titanium oxide layer, an aluminum oxide layer, and an amorphous silicon layer, but is not limited thereto.

The second encapsulation layer TFE2 may be disposed on the first encapsulation layer TFE1. The second encapsulation layer TFE2 may include an organic material which protects the light emitting element layer EML from foreign substances such as, for example, dust. The second encapsulation layer TFE2 may extend to the dam DAM beyond the display area DA. The second encapsulation layer TFE2 may fill and be formed in an area surrounded by the dam DAM. For example, the second encapsulation layer TFE2 may include an organic film formed of an acrylic resin, an epoxy resin, a phenolic resin, a polyamide resin, a polyimide resin, or the like. The second encapsulation layer TFE2 may be formed by curing a monomer or applying a polymer.

The third encapsulation layer TFE3 may be disposed on the second encapsulation layer TFE2. The third encapsulation layer TFE3 may include an inorganic material and prevent oxygen or moisture from permeating into the light emitting element layer EML. The third encapsulation layer TFE3 may extend to the edge of the planarization layer OC beyond the display area DA and the dam DAM. The third encapsulation layer TFE3 may be disposed on the second encapsulation layer TFE2 inside the dam DAM, and the third encapsulation layer TFE3 may be disposed on the first encapsulation layer TFE1 at the edge of the planarization layer OC. For example, the third encapsulation layer TFE3 may be formed of a same material included in the first encapsulation layer TFE1.

The dam DAM may surround the display area DA. The dam DAM may include the same material as the pixel defining film PDL and may be formed in the same process as the pixel defining film PD. The dam DAM may have a predetermined height such that the second encapsulation layer TFE2 including the organic material does not extend beyond the dam DAM.

The anti-static circuit ESD may be disposed between the display area DA and the pad area PAD. The anti-static circuit ESD may include at least one transistor. The anti-static circuit ESD may be electrically connected to the second connection line CWL2. Accordingly, the anti-static circuit ESD may prevent static electricity introduced from the outside from being introduced into the display area DA through the second connection line CWL2.

The plate PLT may include an open part SOP. The open part SOP of the plate PLT may be etched from a lower surface of the plate PLT and penetrate up to an upper surface of the plate PLT. For example, a width of a lower portion of the open part SOP may be greater than a width of an upper portion of the open part SOP. In the manufacturing process of the display device 10, the lower surface of the lower film PRF and the lower surface of the pad part PAD may be exposed through the open part SOP. The pad part PAD may be electrically connected to the printed circuit unit FPCA through the flexible film COF inserted into the open part SOP.

The flexible film COF may be disposed below the lower film PRF. One side of the flexible film COF may be inserted into the open part SOP of the plate PLT and electrically connected to the pad part PAD. The flexible film COF may include the first lead electrode LDE1 disposed on an upper surface of one side of the flexible film COF and inserted into the open part SOP. The first lead electrode LDE1 may be in contact with the lower surface of the pad part PAD.

The flexible film COF may include a second lead electrode LDE2 disposed on an upper surface of another side of the flexible film COF. The second lead electrode LDE2 may be electrically connected to the printed circuit unit FPCA disposed on the lower surface of the plate PLT. The flexible film COF may transmit a signal and a voltage of the printed circuit board FPCA to the display area DA. The flexible film COF may supply a scan control signal to the scan driver SIC.

The printed circuit unit FPCA may be disposed on the lower surface of the plate PLT. The printed circuit unit FPCA may include at least one of a driving integrated circuit, a timing controller, and a power supply unit. The printed circuit unit FPCA may convert digital video data into an analog data voltage based on a data control signal, and may supply the analog data voltage to the data line DL of the display area DA through the flexible film COF. The printed circuit unit FPCA may supply a source voltage to the power line VL of the display area DA through the flexible film COF. The display device 10 may include the first connection line CWL1 disposed on the second substrate SUB2, the pad part PAD penetrating through the first and second substrates SUB1 and SUB2, and the flexible film COF and the printed circuit unit FPCA disposed below the lower film PRF, which may minimize an area of the display area NDA.

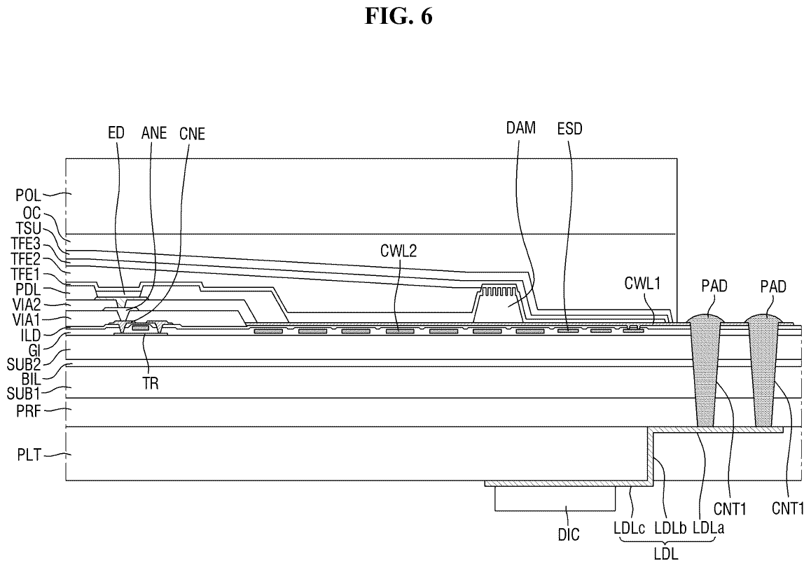

FIG. 6 is a cross-sectional view illustrating a portion of a display device according to another example embodiment. The display device of FIG. 6 is different from the display device of FIG. 5 in configurations of a plate PLT, a lead line LDL, and a display driver DIC, and the same configurations as the configurations described herein will be briefly described or a description thereof will be omitted.

Referring to FIG. 6, the display device 10 may include a plate PLT, a lower film PRF, a first substrate SUB1, a barrier insulating layer BIL, a second substrate SUB2, a transistor layer TRL, a light emitting element layer EML, an encapsulation layer TFEL, a dam DAM, an anti-static circuit ESD, a touch sensing unit TSU, a planarization layer OC, an optical member POL, a pad part PAD, and a display driver DIC.

The plate PLT may support the display device 10. The plate PLT may include a material having excellent permeability and heat resistance. For example, the plate PLT may be formed of a glass fiber reinforced polymer (GFRP), but is not limited thereto.

The plate PLT may include the lead line LDL. The lead line LDL may include a first portion LDLa disposed on an upper surface of the plate PLT, a second portion LDLb connected to the first portion LDLa and penetrating through the plate PLT, and a third portion LDLc connected to the second portion LDLb and disposed on a lower surface of the plate PLT. The lead line LDL may extend from the lower surface of the plate PLT to the upper surface of the plate PLT in the thickness direction of the plate PLT. The first portion LDLa of the lead line LDL may be in contact with a lower surface of the pad part PAD disposed on the upper surface of the plate PLT, and the third portion LDLc of the lead line LDL may be electrically connected to the display driver DIC disposed on the lower surface of the plate PLT. The plate PLT including the lead line LDL may be attached to the lower surface of the lower film PRF after the pad part PAD is completed. The plate PLT may be attached to the lower surface of the lower film PRF through an adhesive member (not illustrated). The pad part PAD may be electrically connected to the display driver DIC through a lead line LDL built into the plate PLT.

The display driver DIC may be mounted on the lower surface of the plate PLT. The display driver DIC may be an integrated circuit (IC). The display driver DIC may convert digital video data into an analog data voltage based on a data control signal received from a timing controller (not illustrated), and the display driver DIC may supply the analog data voltage to the data line DL of the display area DA through the flexible film COF. The display driver DIC may supply a source voltage received from a power supply unit (not illustrated) to the power line VL of the display area DA through the flexible film COF. The display driver DIC may supply a scan control signal to the scan driver SIC through the flexible film COF. The display device 10 may include the first connection line CWL1 disposed on the second substrate SUB2, the pad part PAD penetrating through the first and second substrates SUB1 and SUB2, and the lead line LDL and the display driver DIC disposed below the lower film PRF, which may minimize an area of the display area NDA.

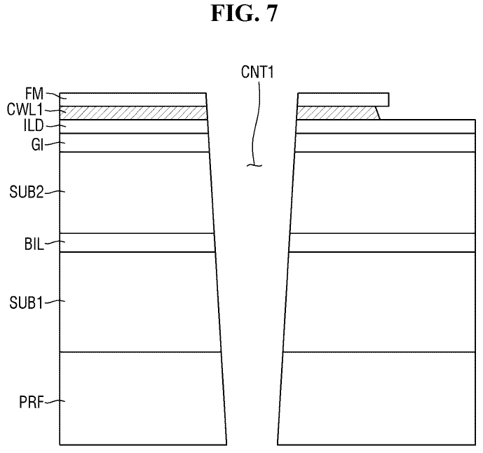

FIGS. 7 to 9 are cross-sectional views illustrating an example of a manufacturing process of a pad part in the display devices of FIGS. 5 and 6.

In FIG. 7, the manufacturing process may include disposing the first substrate SUB1 on the lower film PRF. The first substrate SUB1 may be a base substrate or a base member. The manufacturing process may include disposing the barrier insulating layer BIL on the first substrate SUB1. The barrier insulating layer BIL may include an inorganic film capable of preventing permeation of air or moisture. The manufacturing process may include disposing the second substrate SUB2 on the barrier insulating layer BIL. The second substrate SUB2 may be a base substrate or a base member.

The manufacturing process may include disposing the gate insulating layer GI on the second substrate SUB2. The manufacturing process may include disposing the interlayer insulating layer ILD on the gate layer GTL. The manufacturing process may include disposing the first connection line CWL1 on the interlayer insulating layer ILD. The first connection line CWL1 may include the same material as the first source metal layer SDL1 of the display area DA and may be formed in the same process as the first source metal layer SDL1. The manufacturing process may include disposing a protective film FM on the first connection line CWL1.

The first contact hole CNT1 may penetrate through the protective film FM, the first connection line CWL1, the interlayer insulating layer ILD, the gate insulating layer GI, the second substrate SUB2, the barrier insulating layer BIL, the first substrate SUB1, and the lower film PRF. The manufacturing process may include etching the first contact hole CNT1 from an upper surface of the protective film FM, and the first contact hole CNT1 may penetrate up to the lower surface of the lower film PRF.

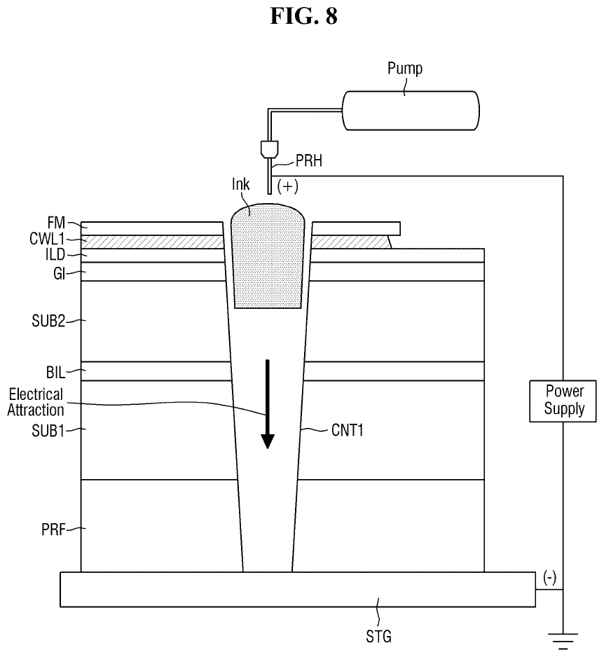

In FIG. 8, the manufacturing process may include providing the protective film FM, the first connection line CWL1, the interlayer insulating layer ILD, the gate insulating layer GI, the second substrate SUB2, the barrier insulating layer BIL, the first substrate SUB1, and the lower film PRF that include the first contact hole CNT1 on a stage STG.

For example, the manufacturing process may include applying conductive ink Ink to the first contact hole CNT1 through an electrohydrodynamic (EHD) jet printing method. A droplet of the conductive ink Ink may be smaller than a diameter of the first contact hole CNT1. The first contact hole CNT1 may have a width in micrometer (μm) units. For example, the width of the first contact hole CNT1 may be 40 μm or less.

The manufacturing process may include injecting, by a pump, the conductive ink Ink into the first contact hole CNT1 through a print head PRH. A diameter of the print head PRH may be 0.3 to 30 μm. The conductive ink Ink may have a droplet size in nanometer (nm) units. For example, the droplet size of the conductive ink Ink may be 500 nm or more. The manufacturing process may include receiving, at the print head PRH, a positive voltage (+) from a power supply. The manufacturing process may include receiving, at the stage STG, a negative voltage (−) from the power supply. Descriptions of injecting the conductive ink Ink through the print head PRH may also be referred to as discharging the conductive ink Ink via the print head PRH.

The manufacturing process may include disposing the first contact hole CNT1 between the print head PRH and the stage STG to form an electric field, and the conductive ink Ink may be discharged from the print head PRH and have a positive charge. Fluidity of the conductive ink Ink may be improved by electrical attraction, and the conductive ink Ink may fill the first contact hole CNT1 having a micro size. Accordingly, the conductive ink Ink may easily fill up to the lowermost portion of the first contact hole CNT1 through the electrohydrodynamic (EHD) jet printing method.

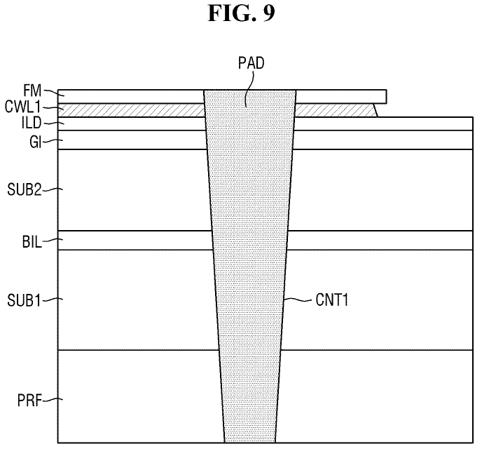

In FIG. 9, the manufacturing process may include forming the pad part PAD by low temperature sintering of the conductive ink Ink including nanoparticles and a polymer. The conductive ink Ink filling the first contact hole CNT1 may include the polymer as a binder binding metal particles to each other, and the nanoparticles may be in close contact with each other and agglomerate through a sintering process. The pad part PAD may have conductivity by including the sintered nanoparticles. The manufacturing process may include removing the protective film FM after the pad part PAD is formed.

In connection with FIG. 5, the manufacturing process may include disposing the plate PLT including the open part SOP below the lower film PRF. The manufacturing process may include inserting the first lead electrode LDE1 of the flexible film COF into the open part SOP and pressing the first lead electrode LDE1 to the lower surface of the pad part PAD.

In connection with FIG. 6, the manufacturing process may include disposing the plate PLT including the lead line LDL below the lower film PRF. The manufacturing process may include pressing the lead line LDL built into the plate PLT to the lower surface of the pad part PAD.

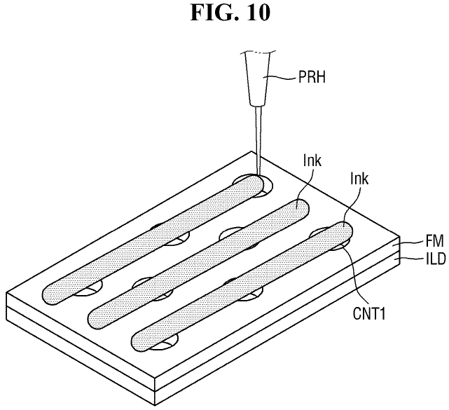

FIGS. 10 to 12 are perspective views illustrating an example of a manufacturing process of the pad part in the display devices of FIGS. 5 and 6. FIGS. 10 to 12 are perspective views illustrating the manufacturing process of the pad part in the display devices of FIGS. 8 and 9.

Referring to FIG. 10, the manufacturing process may include applying, by the print head PRH, the conductive ink Ink in a linear direction (e.g., a straight line direction). In an example in which a plurality of first contact holes CNT1 are disposed in three rows, the print head PRH may apply the conductive ink Ink three times, but an application method of the print head PRH is not limited thereto.

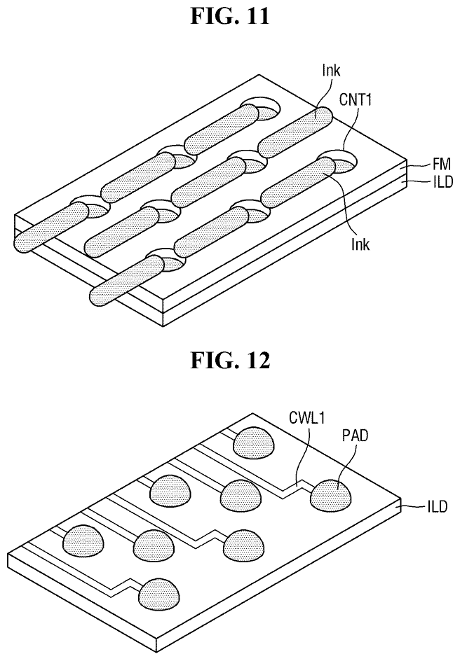

In FIG. 11, the manufacturing process may include disposing the conductive ink Ink in a specific direction such that portions of the conductive ink Ink fill the first contact holes CNT1 and other portions of the conductive ink Ink are applied onto the protective film FM between the first contact holes CNT1.

In FIG. 12, the manufacturing process may include forming the pad parts PAD by sintering the conductive ink Ink. The manufacturing process may include removing the protective film FM and the conductive ink Ink applied onto the protective film FM, which may expose the first connection line CWL1 and the interlayer insulating layer ILD.

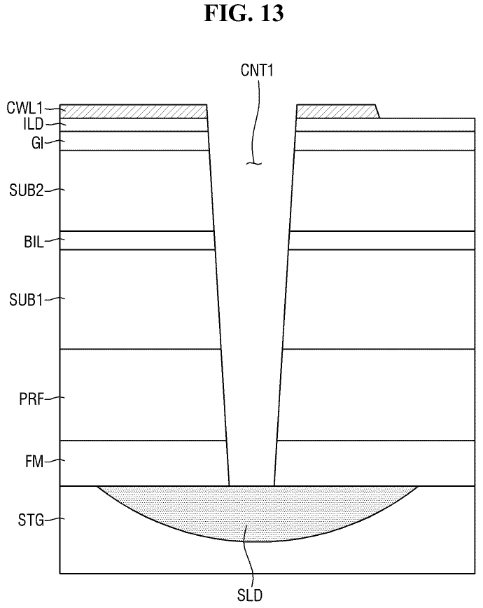

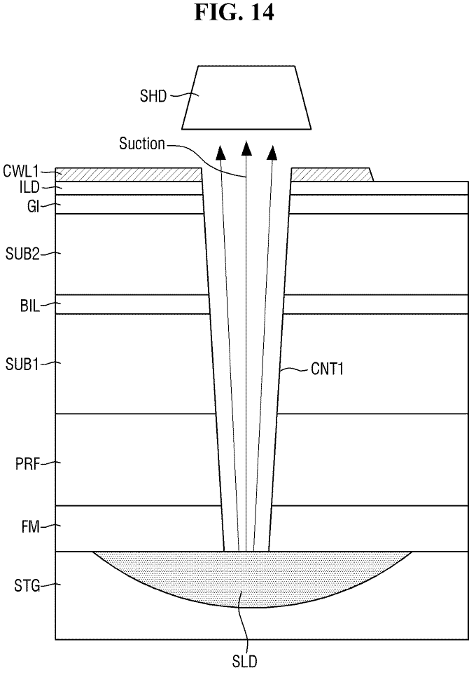

FIGS. 13 to 16 are cross-sectional views illustrating another example of a manufacturing process of the pad part in the display devices of FIGS. 5 and 6. A manufacturing process described with reference to FIG. 13 corresponds to a step after the manufacturing process described with reference to FIG. 7.

In FIG. 13, the manufacturing process may include providing the first connection line CWL1, the interlayer insulating layer ILD, the gate insulating layer GI, the second film PRF that include the first contact hole CNT1 on a protective film FM disposed on the stage STG. The manufacturing process may include providing soldering ink SLD at an upper portion of the stage STG and disposing the first contact hole CNT1 to overlap the soldering ink SLD.

The soldering ink SLD may include nanoparticles and a polymer. The nanoparticles may include nanoscale metal particles such as, for example, silver (Ag), copper (Cu), aluminum (Al), or chromium (Cr), and the polymer may include an acrylic resin or an epoxy resin, but embodiments of the present disclosure are not limited thereto.

In FIG. 14, the manufacturing process may include suctioning the soldering ink SLD into the first contact hole CNT1 by a suction device SHD. The soldering ink SLD may fill the first contact hole CNT1, from a lower portion of the first contact hole CNT1 to an upper portion of the first contact hole CNT1. The manufacturing process may include suctioning the soldering ink SLD until the soldering ink SLD comes into contact with the first connection line CWL1.

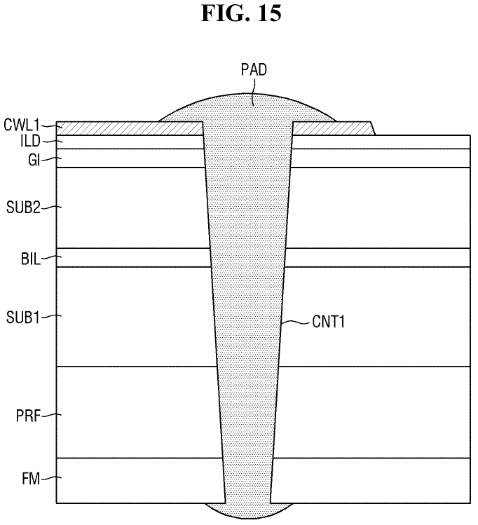

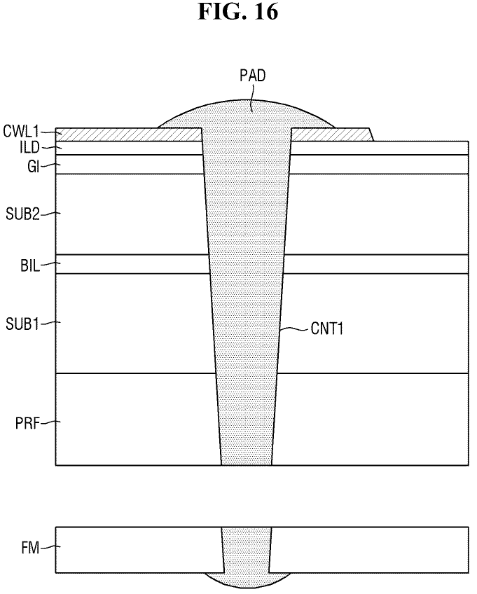

In FIG. 15, the manufacturing process may include forming the pad part PAD by sintering the soldering ink SLD. The pad part PAD may be in contact with side surfaces of the first connection line CWL1 forming the first contact hole CNT1 and the upper surface of the first connection line CWL1.

In FIG. 16, the manufacturing process may include removing the protective film FM and a portion of the pad part PAD surrounded by the protective film FM. The lower surface of the lower film PRF and the lower surface of the pad part PAD may be exposed. The lower surface of the pad part PAD may be disposed on the same plane as the lower surface of the lower film PRF.

In connection with FIG. 5, the manufacturing process may include disposing the plate PLT including the open part SOP below the lower film PRF. The manufacturing process may include inserting the first lead electrode LDE1 of the flexible film COF into the open part SOP and pressing the first lead electrode LDE1 to the lower surface of the pad part PAD.

In connection with FIG. 6, the manufacturing process may include disposing the plate PLT including the lead line LDL below the lower film PRF. The manufacturing process may include pressing the lead line LDL built into the plate PLT to the lower surface of the pad part PAD.

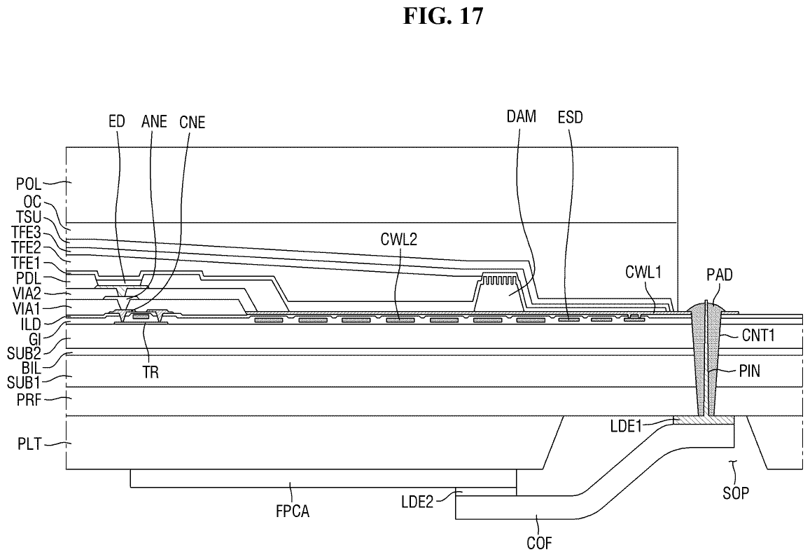

FIG. 17 is a cross-sectional view illustrating a portion of a display device according to another example embodiment. The display device of FIG. 17 is different from the display device of FIG. 5 in a configuration of the first lead electrode LDE1, and the same configurations as the configurations described herein will be briefly described or a description thereof will be omitted.

Referring to FIG. 17, the display device 10 may include a plate PLT, a lower film PRF, a first substrate SUB1, a barrier insulating layer BIL, a second substrate SUB2, a transistor layer TRL, a light emitting element layer EML, an encapsulation layer TFEL, a dam DAM, an anti-static circuit ESD, a touch sensing unit TSU, a planarization layer OC, an optical member POL, a pad part PAD, a flexible film COF, and a printed circuit unit FPCA.

The pad part PAD may be disposed on the first connection line CWL1 and inserted into the first contact hole CNT1. The first contact hole CNT1 may penetrate through the first connection line CWL1, the interlayer insulating layer ILD, the gate insulating layer GI, the second substrate SUB2, the barrier insulating layer BIL, the first substrate SUB1, and the lower film PRF. The first contact hole CNT1 may be etched from the upper surface of the first connection line CWL1 and penetrate up to the lower surface of the lower film PRF. The upper surface of the pad part PAD may protrude from the upper surface of the first connection line CWL1, and the lower surface of the pad part PAD may be disposed on the same plane as the lower surface of the lower film PRF. The pad part PAD may be in contact with a pin part PIN penetrating through the pad part PAD and protruding from the upper surface of the first lead electrode LDE1. The pad part PAD may electrically connect the first connection line CWL1 and the first lead electrode LDE1 of the flexible film COF to each other.

The display device 10 includes a plurality of micro-holes penetrating through the first connection line CWL1, the interlayer insulating layer ILD, the gate insulating layer GI, the second substrate SUB2, the barrier insulating layer BIL, the first substrate SUB1, and the lower film PRF, and thus, aspects of the display device 10 described herein may minimize an area of the non-display area NDA and simplify a manufacturing process to reduce manufacturing time and manufacturing costs.

The plate PLT may include an open part SOP. The open part SOP of the plate PLT may be etched from the lower surface of the plate PLT and penetrate up to the upper surface of the plate PLT. For example, a width of a lower portion of the open part SOP may be greater than a width of an upper portion of the open part SOP. The pad part PAD may be electrically connected to the printed circuit unit FPCA through the flexible film COF inserted into the open part SOP.

The flexible film COF may be disposed below the lower film PRF. One side of the flexible film COF may be inserted into the open part SOP of the plate PLT and may be electrically connected to the pad part PAD. The flexible film COF may include the first lead electrode LDE1 disposed on an upper surface of one side of the flexible film COF and inserted into the open part SOP. The upper surface of the first lead electrode LDE1 may be in contact with the lower surface of the pad part PAD.

The first lead electrode LDE1 may include the pin part PIN protruding from the upper surface of the first lead electrode LDE1. The pin part PIN may penetrate through the pad part PAD inserted into the first contact hole CNT1 and protrude from the upper surface of the pad part PAD. The pin part PIN may increase a contact area with the pad part PAD, which may support easily connecting the pad part PAD and the first lead electrode LDE1 to each other.

The display device 10 may include the first connection line CWL1 disposed on the second substrate SUB2, the pad part PAD and the pin part PIN penetrating through the first and second substrates SUB1 and SUB2, and the flexible film COF and the printed circuit unit FPCA disposed below the lower film PRF, which may minimize an area of the display area NDA.

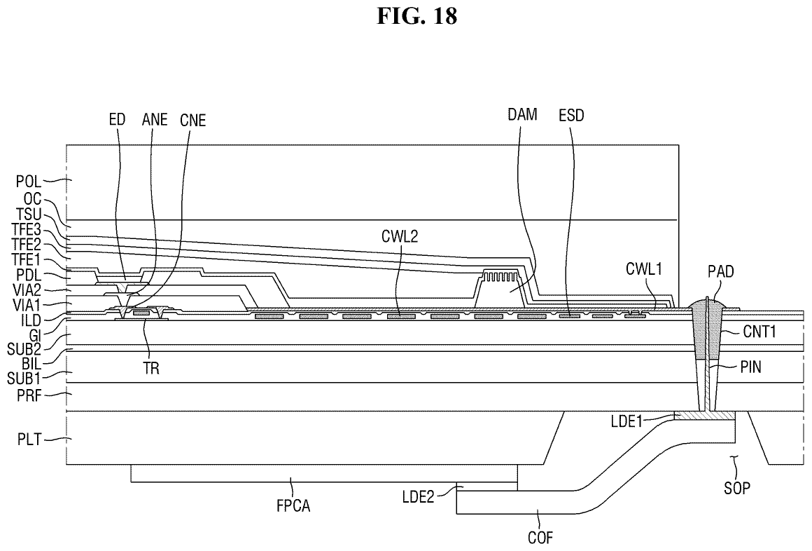

FIG. 18 is a cross-sectional view illustrating a portion of a display device according to another example embodiment. The display device of FIG. 18 is different from the display device of FIG. 17 in a configuration of the pad part PAD, and the same configurations as the configurations described herein will be briefly described or a description thereof will be omitted.

Referring to FIG. 18, the display device 10 may include a plate PLT, a lower film PRF, a first substrate SUB1, a barrier insulating layer BIL, a second substrate SUB2, a transistor layer TRL, a light emitting element layer EML, an encapsulation layer TFEL, a dam DAM, an anti-static circuit ESD, a touch sensing unit TSU, a planarization layer OC, an optical member POL, a pad part PAD, a flexible film COF, and a printed circuit unit FPCA.

The pad part PAD may be disposed on the first connection line CWL1 and inserted into the first contact hole CNT1. The first contact hole CNT1 may penetrate through the first connection line CWL1, the interlayer insulating layer ILD, the gate insulating layer GI, the second substrate SUB2, the barrier insulating layer BIL, the first substrate SUB1, and the lower film PRF. The first contact hole CNT1 may be etched from the upper surface of the first connection line CWL1 and penetrate up to the lower surface of the lower film PRF. The upper surface of the pad part PAD may protrude from the upper surface of the first connection line CWL1, and the lower surface of the pad part PAD may be spaced apart from the upper surface of the first lead electrode LDE1. Accordingly, the pad part PAD may not be filled into a lower portion of the first contact hole CNT1. The pad part PAD may be in contact with the pin part PIN penetrating through the pad part PAD. The pad part PAD may electrically connect the first lead electrode LDE1 of the flexible film COF and the first connection line CWL1 to each other.

The flexible film COF may be disposed below the lower film PRF. One side of the flexible film COF may be inserted into the open part SOP of the plate PLT and may be electrically connected to the pad part PAD. The flexible film COF may include the first lead electrode LDE1 disposed on an upper surface of one side of the flexible film COF and inserted into the open part SOP. The upper surface of the first lead electrode LDE1 may be spaced apart the lower surface of the pad part PAD.

The first lead electrode LDE1 may include the pin part PIN protruding from the upper surface of the first lead electrode LDE1. The pin part PIN may penetrate through the pad part PAD inserted into the first contact hole CNT1 and protrude from the upper surface of the pad part PAD. The pin part PIN may increase a contact area with the pad part PAD, and may easily connect the pad part PAD and the first lead electrode LDE1 to each other.

The display device 10 may minimize an area of the display area NDA by including the first connection line CWL1 disposed on the second substrate SUB2, the pad part PAD and the pin part PIN penetrating through the first and second substrates SUB1 and SUB2, and the flexible film COF and the printed circuit unit FPCA disposed below the lower film PRF.

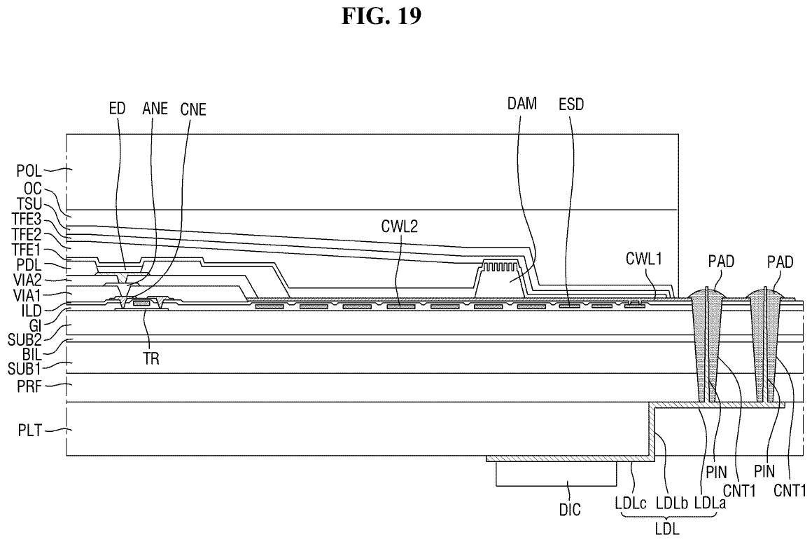

FIG. 19 is a cross-sectional view illustrating a portion of a display device according to another embodiment. The display device of FIG. 19 is different from the display device of FIG. 17 in a configuration of the lead line LDL, and the same configurations as the configurations described herein will be briefly described or a description thereof will be omitted.

Referring to FIG. 19, the display device 10 may include a plate PLT, a lower film PRF, a first substrate SUB1, a barrier insulating layer BIL, a second substrate SUB2, a transistor layer TRL, a light emitting element layer EML, an encapsulation layer TFEL, a dam DAM, an anti-static circuit ESD, a touch sensing unit TSU, a planarization layer OC, an optical member POL, a pad part PAD, and a display driver DIC.

The pad part PAD may be disposed on the first connection line CWL1 and inserted into the first contact hole CNT1. The first contact hole CNT1 may penetrate through the first connection line CWL1, the interlayer insulating layer ILD, the gate insulating layer GI, the second substrate SUB2, the barrier insulating layer BIL, the first substrate SUB1, and the lower film PRF. The first contact hole CNT1 may be etched from the upper surface of the first connection line CWL1 and penetrate up to the lower surface of the lower film PRF. The upper surface of the pad part PAD may protrude from the upper surface of the first connection line CWL1, and the lower surface of the pad part PAD may be disposed on the same plane as the lower surface of the lower film PRF. The pad part PAD may be in contact with a pin part PIN penetrating through the pad part PAD and an upper surface of a first portion LDLa of the lead line LDL. The pad part PAD may electrically connect the lead line LDL and the first connection line CWL1 to each other.

The plate PLT may include the lead line LDL. The lead line LDL may include a first portion LDLa disposed on the upper surface of the plate PLT, a second portion LDLb connected to the first portion LDLa and penetrating through the plate PLT, and a third portion LDLc connected to the second portion LDLb and disposed on the lower surface of the plate PLT. The lead line LDL may extend from the lower surface of the plate PLT to the upper surface of the plate PLT in the thickness direction of the plate PLT. The first portion LDLa of the lead line LDL may be in contact with the lower surface of the pad part PAD disposed on the upper surface of the plate PLT, and the third portion LDLc of the lead line LDL may be electrically connected to the display driver DIC disposed on the lower surface of the plate PLT. The plate PLT including the lead line LDL may be attached to the lower surface of the lower film PRF. The plate PLT may be attached to the lower surface of the lower film PRF through an adhesive member (not illustrated). The pad part PAD may be electrically connected to the display driver DIC through a lead line LDL built into the plate PLT.

The lead line LDL may include the pin part PIN protruding from the upper surface of the first portion LDLa. The pin part PIN may penetrate through the pad part PAD inserted into the first contact hole CNT1 and protrude from the upper surface of the pad part PAD. The pin part PIN may increase a contact area with the pad part PAD, and may easily connect the pad part PAD and the lead line LDL to each other.

The display device 10 may include the first connection line CWL1 disposed on the second substrate SUB2, the pad part PAD and the pin part PIN penetrating through the first and second substrates SUB1 and SUB2, and the lead line LDL and the display driver DIC disposed below the lower film PRF, which may minimize an area of the display area NDA.

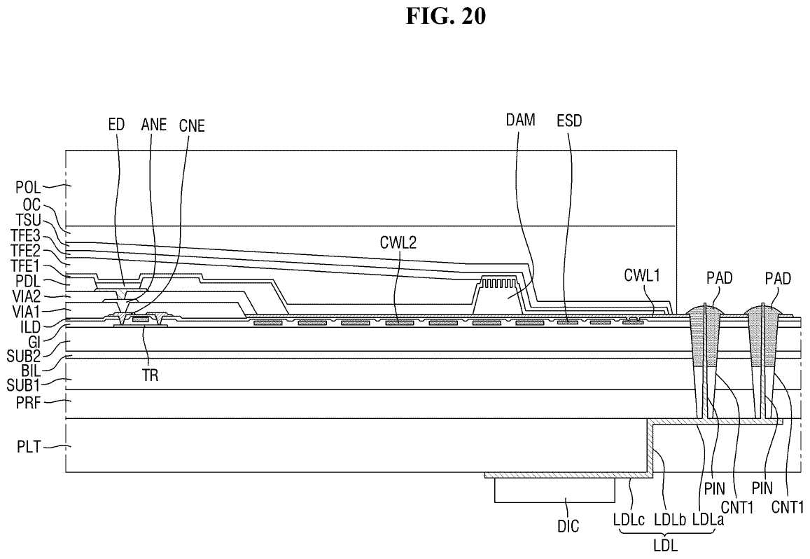

FIG. 20 is a cross-sectional view illustrating a portion of a display device according to another example embodiment. The display device of FIG. 20 is different from the display device of FIG. 19 in a configuration of the pad part PAD, and the same configurations as the configurations described herein will be briefly described or a description thereof will be omitted.

Referring to FIG. 20, the display device 10 may include a plate PLT, a lower film PRF, a first substrate SUB1, a barrier insulating layer BIL, a second substrate SUB2, a transistor layer TRL, a light emitting element layer EML, an encapsulation layer TFEL, a dam DAM, an anti-static circuit ESD, a touch sensing unit TSU, a planarization layer OC, an optical member POL, a pad part PAD, and a display driver DIC.

The pad part PAD may be disposed on the first connection line CWL1 and inserted into the first contact hole CNT1. The first contact hole CNT1 may penetrate through the first connection line CWL1, the interlayer insulating layer ILD, the gate insulating layer GI, the second substrate SUB2, the barrier insulating layer BIL, the first substrate SUB1, and the lower film PRF. The first contact hole CNT1 may be etched from the upper surface of the first connection line CWL1 and penetrate up to the lower surface of the lower film PRF. The upper surface of the pad part PAD may protrude from the upper surface of the first connection line CWL1, and the lower surface of the pad part PAD may be spaced apart from the upper surface of the first portion LDLa of the lead line DLD. Accordingly, the pad part PAD may not be filled into a lower portion of the first contact hole CNT1. The pad part PAD may be in contact with the pin part PIN penetrating through the pad part PAD. The pad part PAD may electrically connect the lead line LDL and the first connection line CWL1 to each other.

The plate PLT may include the lead line LDL. The lead line LDL may include a first portion LDLa disposed on the upper surface of the plate PLT, a second portion LDLb connected to the first portion LDLa and penetrating through the plate PLT, and a third portion LDLc connected to the second portion LDLb and disposed on the lower surface of the plate PLT. The lead line LDL may extend from the lower surface of the plate PLT to the upper surface of the plate PLT through the thickness direction of the plate PLT. The first portion LDLa of the lead line LDL may be in contact with the lower surface of the pad part PAD disposed on the upper surface of the plate PLT, and the third portion LDLc of the lead line LDL may be electrically connected to the display driver DIC disposed on the lower surface of the plate PLT. The plate PLT including the lead line LDL may be attached to the lower surface of the lower film PRF. The plate PLT may be attached to the lower surface of the lower film PRF through an adhesive member (not illustrated). The pad part PAD may be electrically connected to the display driver DIC through a lead line LDL built into the plate PLT.

The lead line LDL may include the pin part PIN protruding from the upper surface of the first portion LDLa. The pin part PIN may penetrate through the pad part PAD inserted into the first contact hole CNT1 and protrude from the upper surface of the pad part PAD. The pin part PIN may increase a contact area with the pad part PAD, and may easily connect the pad part PAD and the lead line LDL to each other.

The display device 10 may minimize an area of the display area NDA by including the first connection line CWL1 disposed on the second substrate SUB2, the pad part PAD and the pin part PIN penetrating through the first and second substrates SUB1 and SUB2, and the lead line LDL and the display driver DIC disposed below the lower film PRF.

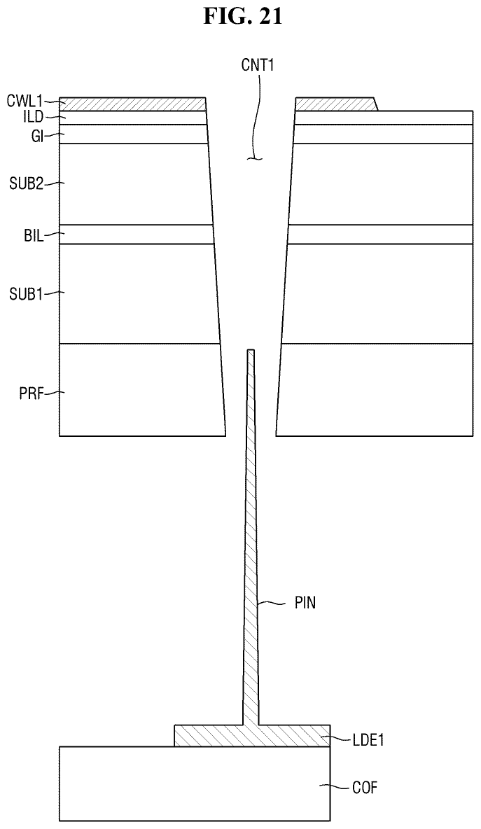

FIGS. 21 to 23 are cross-sectional views illustrating a manufacturing process of a pad part in the display devices of FIGS. 17 to 20.

In FIG. 21, the manufacturing process may include disposing the first substrate SUB1 on the lower film PRF. The first substrate SUB1 may be a base substrate or a base member. The manufacturing process may include disposing the barrier insulating layer BIL on the first substrate SUB1. The barrier insulating layer BIL may include an inorganic film capable of preventing permeation of air or moisture. The manufacturing process may include disposing the second substrate SUB2 on the barrier insulating layer BIL. The second substrate SUB2 may be a base substrate or a base member.

The manufacturing process may include disposing the gate insulating layer GI on the second substrate SUB2. The manufacturing process may include disposing the interlayer insulating layer ILD on the gate layer GTL. The manufacturing process may include disposing the first connection line CWL1 on the interlayer insulating layer ILD. The first connection line CWL1 may include the same material as the first source metal layer SDL1 of the display area DA and may be formed in the same process as the first source metal layer SDL1.

The first contact hole CNT1 may penetrate through the first connection line CWL1, the interlayer insulating layer ILD, the gate insulating layer GI, the second film PRF. The manufacturing process may include etching the first contact hole CNT1 from the upper surface of the first connection line CWL1 such that the first contact hole CNT1 penetrates up to the lower surface of the lower film PRF.

The manufacturing process may include providing the flexible film COF below the lower film PRF. The flexible film COF may include the first lead electrode LDE1 disposed on an upper surface of one side of the flexible film COF and inserted into the open part SOP. The first lead electrode LDE1 may include the pin part PIN protruding from the upper surface of the first lead electrode LDE1.

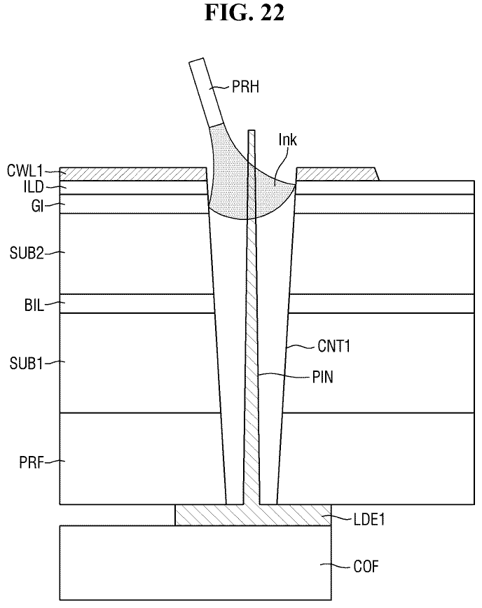

In FIG. 22, the upper surface of the first lead electrode LDE1 may be disposed on the lower surface of the lower film PRF, and the pin part PIN may be inserted into the first contact hole CNT1. The pin part PIN may be spaced apart from inner sidewalls of the first contact hole CNT1.

The manufacturing process may include injecting, by a print head PRH, conductive ink Ink into the first contact hole CNT1. A diameter of the print head PRH may be 0.3 to 30 μm. The conductive ink Ink may have a droplet size in nanometer (nm) units. For example, the droplet size of the conductive ink Ink may be 500 nm or more. The conductive ink Ink may fill the first contact hole CNT1 into which the pin part PIN is inserted.

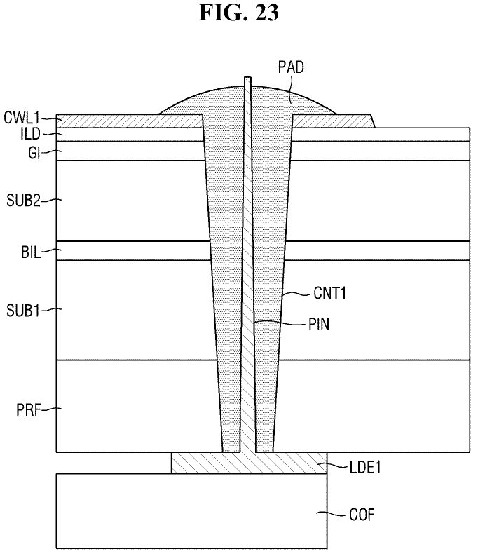

In FIG. 23, the manufacturing process may include forming the pad part PAD by low temperature sintering of the conductive ink Ink including nanoparticles and a polymer. The conductive ink Ink filled into the first contact hole CNT1 may include the polymer as a binder binding metal particles to each other, and the nanoparticles may be in close contact with each other and agglomerate through a sintering process. The pad part PAD may have conductivity by including the sintered nanoparticles. The pin part PIN may protrude from the upper surface of the pad part PAD. The manufacturing process may include removing the protective film FM after the pad part PAD is formed.

In connection with FIG. 17, the manufacturing process may include disposing the plate PLT including the open part SOP below the lower film PRF. The manufacturing process may include pressing the first lead electrode LDE1 of the flexible film COF to the lower surface of the pad part PAD.

In connection with FIG. 19, the manufacturing process may include disposing the plate PLT including the lead line LDL below the lower film PRF. The manufacturing process may include pressing the lead line LDL built into the plate PLT to the lower surface of the pad part PAD.

Unlike the example illustrated in FIG. 23, the lower surface of the pad part PAD may be spaced apart from the upper surface of the first lead electrode LDE1. In this case, the pad part PAD may not be filled into a lower portion of the first contact hole CNT1. In connection with FIG. 18, the pad part PAD may be in contact with the pin part PIN penetrating through the pad part PAD and electrically connect the first lead electrode LDE1 and the first connection line CWL1 to each other. In connection with FIG. 20, the pad part PAD may be in contact with the pin part PIN penetrating through the pad part PAD and electrically connect the lead line LDL and the first connection line CWL1 to each other.

Embodiments of the present disclosure support one or more processes (manufacturing processes) supportive of the features and embodiments described herein. Descriptions that an element “may be disposed,” “may be formed,” and the like include processes and techniques for disposing, forming, positioning, and modifying the element and the like in accordance with example aspects described herein.

What is claimed is:

1. A display device comprising:
a plate comprising an open part;
a lower film disposed on the plate;
a first substrate disposed on the lower film;
a first connection line disposed on the first substrate;
a pad part inserted into a first contact hole penetrating through the first connection line, the first substrate, and the lower film, wherein the pad part is connected to the first connection line; and
a flexible film comprising a first lead electrode inserted into the open part of the plate,
wherein the first lead electrode comprises a pin part protruding from an upper surface of the first lead electrode and penetrating through the pad part.

2. The display device of claim 1, wherein a lower surface of the pad part is in contact with the upper surface of the first lead electrode.

3. The display device of claim 1, wherein a lower surface of the pad part is spaced apart from the upper surface of the first lead electrode.

4. The display device of claim 1, further comprising:
a gate insulating layer disposed on the first substrate;
a second connection line disposed on the gate insulating layer and connected to the first connection line; and
an interlayer insulating layer disposed between the second connection line and the first connection line.

5. The display device of claim 4, further comprising:
a semiconductor region of a transistor disposed on the second substrate;
a gate electrode of the transistor disposed on the gate insulating layer; and
a connection electrode disposed on the interlayer insulating layer and electrically connected to the transistor,
wherein the first connection line comprises a same material as the connection electrode and is formed in a same process as the connection electrode, and
the second connection line comprises a same material as the gate electrode of the transistor and is formed in the same process as the gate electrode of the transistor.

6. The display device of claim 1, further comprising a printed circuit unit disposed below the plate and comprising a driving integrated circuit,
wherein the flexible film further comprises a second lead electrode electrically connected to the printed circuit unit.

7. A display device comprising:
a plate comprising a lead line;
a lower film disposed on the plate;
a first substrate disposed on the lower film;
a first connection line disposed on the first substrate; and
a pad part inserted into a first contact hole penetrating through the first connection line, the first substrate, and the lower film, wherein the pad part is connected to the first connection line,
wherein the lead line comprises:
a first portion disposed on an upper surface of the plate;
a second portion penetrating through the plate and connected to the first portion;
a third portion disposed on a lower surface of the plate and connected to the second portion; and
a pin part protruding from an upper surface of the first portion and penetrating through the pad part.

8. The display device of claim 7, wherein a lower surface of the pad part is in contact with the upper surface of the first portion of the lead line.

9. The display device of claim 7, wherein a lower surface of the pad part is spaced apart from the upper surface of the first portion of the lead line.

10. The display device of claim 7, further comprising a display driver disposed on the lower surface of the plate and electrically connected to the third portion of the lead line.

11. A method of manufacturing a display device, comprising:
sequentially stacking a lower film, a first substrate, a first connection line, and a protective film;
forming a first contact hole penetrating through the protective film, the first connection line, the first substrate, and the lower film;
providing the lower film, the first substrate, the first connection line, and the protective film which comprise the first contact hole, on a stage;
providing a print head over the first contact hole;
supplying a positive voltage to the print head and supplying a negative voltage to the stage, by a power supply;
injecting conductive ink into the first contact hole through the print head;
forming a pad part by sintering the conductive ink;
disposing a plate below the lower film, the plate comprising an open part exposing the pad part; and
connecting a first lead electrode of a flexible film to the pad part by inserting the first lead electrode of the flexible film into the open part.

12. The method of claim 11, wherein the injecting of the conductive ink comprises filling the first contact hole with the conductive ink by electrical attraction of the conductive ink having a positive charge.

13. The method of claim 11, wherein the injecting of the conductive ink comprises injecting a portion of the conductive ink into the first contact hole and applying another portion of the conductive ink onto the protective film, by applying the conductive ink in a linear direction by the print head.

14. The method of claim 13, further comprising, after the forming of the pad part, removing the protective film and the conductive ink applied onto the protective film.

15. A method of manufacturing a display device, comprising:
sequentially stacking a protective film, a lower film, a first substrate, and a first connection line;
forming a first contact hole penetrating through the first connection line, the first substrate, the lower film, and the protective film;
providing a stage including soldering ink provided at an upper portion of the stage;
providing the protective film, the lower film, the first substrate, and the first connection line on the stage such that the first contact hole overlaps the soldering ink;
suctioning the soldering ink into the first contact hole by a suction device; and
forming a pad part by sintering the soldering ink.

16. The method of claim 15, further comprising:
exposing a lower surface of the lower film by removing the protective film;
disposing a plate below the lower film, the plate comprising an open part exposing the pad part; and
connecting a first lead electrode of a flexible film to the pad part by inserting the first lead electrode of the flexible film into the open part.

17. The method of claim 16, wherein the exposing of the lower surface of the lower film comprises disposing a lower surface of the pad part on a same plane as the lower surface of the lower film.

18. A method of manufacturing a display device, comprising:
sequentially stacking a lower film, a first substrate, and a first connection line;
forming a first contact hole penetrating through the first connection line, the first substrate, and the lower film;
providing a first lead electrode disposed on one side of a flexible film and comprising a pin part protruding from an upper surface of the first lead electrode;
disposing the first lead electrode on a lower surface of the lower film by inserting the pin part into the first contact hole;
injecting conductive ink into the first contact hole through a print head; and
forming a pad part by sintering the conductive ink.

19. The method of claim 18, wherein the pin part penetrates through the pad part and protrudes from an upper surface of the pad part.

20. The method of claim 18, wherein the first lead electrode is electrically connected to the first connection line through the pin part and the pad part.
